(19) United States
(12) Patent Application Publication
(10) Pub. No.: US 2018/0154678 A1
(43) Pub. Date: Jun. 7, 2018

(54) Method for Producing a Multi-Layer Body

(71) Applicants: LEONHARD KURZ Stiftung & Co. KG, Furth (DE); OVD Kinegram AG, Zug (DE)

(72) Inventors: Violetta Olszowka, Zirndorf (DE); Rene Staub, Hagendorn (CH)

(21) Appl. No.: 15/569,140

(22) PCT Filed: Apr. 20, 2016
(86) PCT No.: PCT/EP2016/058746

§ 371 Date: Oct. 25, 2017

(30) Foreign Application Priority Data
Apr. 30, 2015 (DE) 10 2015 106 800.1

(51) Int. Cl. B42D 25/465; B42D 25/41; B42D 25/328; B42D 25/337; G03F 7/038; B42D 25/445; B42D 25/324; B42D 25/378; B42D 25/373; B42D 25/351; G03F 7/16; G03F 7/20; G03F 7/32

(52) U.S. Cl. CPC B42D 25/465; B42D 25/41; B42D 25/328; B42D 25/337; G03F 7/038; B42D 25/445; G03F 7/325; B42D 25/378; B42D 25/373; B42D 25/351; G03F 7/16; G03F 7/20; B42D 25/324

(57) ABSTRACT

A method for producing a multilayer body with the steps of
a) applying a first varnish layer made of a water-based photoresist to a surface of a base body;
b) exposing the first varnish layer in a first region, wherein the first varnish layer is not exposed in a second region;
c) removing the first varnish layer in the second region.

The invention relates to a method for producing a multilayer body, a multilayer body obtainable in this way, as well as a security document with such a multilayer body.

In order to generate multilayer bodies with appealing graphic designs, it is known to use photoresists which are exposed and developed corresponding to the desired design.

It is furthermore known to apply a wash varnish in the form of the desired design using the so-called lift-off process and to overlay or cover it with a further layer, for example a metallization or a further varnish. Through treatment with solvent, the wash varnish can then be removed again together with parts of the further layer, with the result that the further layer only remains where no wash varnish has been applied.

Both photoresists and wash varnishes are usually solvent-based. This is associated with several disadvantages.

In multilayer bodies which comprise further varnish layers, these further varnish layers can be etched when a solvent-based varnish is applied, which reduces the quality of such a multilayer body. Furthermore, solvent-based varnishes are not environmentally friendly and have to be disposed of in a laborious manner and at great expense.

In the case of usual wash varnishes, the problem additionally arises that they should usually be highly pigmented and porous in order to ensure the desired detachment function. In particular, however, the above-named porosity limits the achievable resolution and edge definition of the designs generated with such wash varnishes.

The object of the present invention is thus to provide a particularly process-stable method for producing multilayer bodies of particularly high quality, as well as multilayer bodies producible in this way and security documents with such multilayer bodies.

This object is achieved by a method with the features of claim 1, a multilayer body with the features of claim 32 and a security document with the features of claim 33.

Such a method for producing a multilayer body comprises the steps of:

a) applying a first varnish layer made of a water-based photoresist to a surface of a base body;

b) exposing the first varnish layer in a first region, wherein the first varnish layer is not exposed in a second region;

c) removing the first varnish layer in the second region.

Through the use of a water-based photoresist, base bodies with a structured varnish layer which are susceptible to the solvent component in solvent-based varnishes can thus also be provided. In particular, solvent-based varnish layers can thus also be overlaid with the photoresist, without adversely affecting their quality or resolution.

Compared with the printing of water-based varnishes, a greatly improved resolution of up to 25 μm, possibly also up to 10 μm, can be achieved with the described method. When corresponding exposure masks are used in step b), for example high-resolution, finely structured line patterns or other grid patterns can thus be generated. By grid pattern is meant here a regular or irregular arrangement of grid elements spaced apart from each other. Grid elements can be, for example, lines or dots or other geometric shapes. The grid elements and/or the distances between them can in each case be the same or also different.

At the same time, the described method is much more environmentally friendly than the use of solvent-based photoresists. The disposal of the liquid waste that accumulates, and possibly treatment of exhaust air, is thus much simpler and more cost-effective.

During the exposure of the first varnish layer polymeric components of the varnish crosslink, with the result that its molecular weight increases in the exposed first region. The varnish thus loses its water solubility in the first region.

The removal of the varnish in the unexposed second region can thus be simply effected by washing with an aqueous solvent.

In this way, it is possible, in a simple and process-stable manner, to obtain multilayer bodies, in particular in the form of a security element with appealing graphic designs, which can be used for example in security documents, such as banknotes, securities, identity documents, visa documents, passports or credit cards. Use for product labels, road toll vignettes or the like with particularly good protection against forgery is also possible.

Such a security element can be, for example, a transfer film, a laminating film, a security strip, a security window or the like.

The base body preferably comprises at least one second varnish layer made of a solvent-based varnish. As explained above, such a varnish layer is not attacked by the water-based photoresist or by the substances used to develop it. In this way, appealing multi-colored designs can thus be created.

The second varnish layer can be present over the whole surface, and thus form a background for the first varnish layer, or also can be applied partially and itself form a motif or design.

The second varnish layer preferably has a layer thickness of from 0.1 μm to 10 μm, particularly preferably from 0.1 μm to 3 μm.

It is preferred if the first varnish layer is applied to a surface of the second varnish layer.

Furthermore, it is expedient if at least one further layer is applied to the first varnish layer.

Additional design elements can hereby be introduced into the multilayer body. Functional layers, such as for example protective varnish layers, can thus also be integrated.

It is furthermore preferred if, after the application of the at least one further layer, the first varnish layer and the at least one further layer are removed in the first region.

In other words, the at least one further layer remains only where the first varnish layer was not present. The at least one further layer is thus structured as the negative of the first varnish layer and thus forms a motif which complements the motif originally formed by the first varnish layer.

In this embodiment, the water-based photoresist of the first layer thus acts as wash varnish. Compared with usual lift-off processes, in which a wash varnish is printed on, a much higher resolution and edge definition can be achieved because of the structuring of the first varnish layer by exposure and developing.

Aqueous photoresists, compared with usual wash varnishes, are also not appreciably porous after curing, which likewise leads to an improvement in the edge definition in the thus-generated motif.

As no organic solvents are necessary for the removal of the first varnish layer, such a method can also be used in the case of multilayer bodies which contain layers which are not stable in organic solvents.

It is preferred in particular if the first varnish layer and the at least one further layer are removed by treatment with an acidic sodium metaperiodate solution, in particular an aqueous solution of 1.5 wt.-% sodium metaperiodate and 0.05 wt.-% sulfuric acid.

The removal of the first varnish layer is thus an oxidative process. The admixture of acid serves to stabilize the metaperiodate. Instead of sulfuric acid, nitric acid can also be used for example.

The pH of the sodium metaperiodate solution is preferably from 1 to 7, particularly preferably from 2 to 5.

The treatment with the acidic sodium metaperiodate solution is preferably effected at a temperature of from 15° C. to 70° C., preferably from 25° C. to 50° C., and/or with a treatment duration of from 600 s to 1 s, preferably from 120 s to s.

The detachment of the first varnish layer can furthermore be supported by agitation of the solution, targeted flow against the multilayer body, brushing, smearing or sonication.

Furthermore, it is expedient if a non-ionic surfactant is added to the acidic sodium metaperiodate solution, in particular selected from the group ethoxylate, alkoxylates of primary or secondary fatty alcohols, alkyl phenols, ethylene oxide/propylene oxide copolymers, amine ethoxylates, alkyl polyglycolides, fatty amine oxides, fatty acid alkanolamides, fatty acid alkyl glucamides.

Such surfactants act as wetting agents and ensure that the sodium metaperiodate solution completely wets the first varnish layer and the at least one further varnish layer, with the result that the desired detachment result can be achieved.

The concentration of the surfactant is preferably from 0% to 50%, particularly preferably from 0.01% to 3%.

It is further preferred if the at least one further layer is or comprises a third varnish layer, in particular made of a solvent-based varnish.

As already explained, such varnishes are not attacked during the removal of the first varnish layer, with the result that the third varnish layer remains in the second region.

It is preferably a varnish from the group acrylates, polyesters, polyurethanes, copolymers, with a layer thickness of from 0.1 μm to 10 μm, preferably from 0.1 μm to 3 μm.

Furthermore, the at least one further layer can be or comprise a reflective layer.

It can be a metal layer, in particular made of aluminum, copper, silver, gold, chromium or an alloy of the above-named metals.

Alternatively, the reflective layer can also be formed as a layer made of a high refractive index (HRI) material, in particular made of zinc sulfide or titanium dioxide.

The reflective layer can, however, also consist of a sequence of layers, in particular of a thin metal layer, a transparent spacer layer and an opaque metallic reflective layer or an HRI layer, a transparent spacer layer with made of a material with a low refractive index and a further HRI layer. One or more of the metal layer, spacer layer, reflective layer can be provided over the whole surface or also only partially.

The reflective layer can also have a sequence of a metal layer, which is in particular provided only partially, and an HRI layer. The HRI layer can be provided over the whole surface or likewise partially.

The layer thickness of a metallic reflective layer is preferably from 5 nm to 150 nm, particularly preferably from 10 nm to 50 nm. The layer thickness of HRI layers is preferably 30 nm to 250 nm. In the thickness range from 30 nm to 75 nm a more color-neutral reflection results, while in the case of thicker layers the light reflected by the reflective layer displays pronounced colors.

Furthermore, it is preferred if the first varnish layer is applied to a reflective layer of the base body and, before the application of the at least one further layer, the reflective layer of the base body is removed in the second region, in particular by etching.

This is advantageous in particular if the at least one further layer is or comprises a reflective layer. Two reflective layers, preferably made of different materials and thus with different optical appearances, can thus be applied precisely registered relative to each other and complementing each other.

It is further preferred if the first varnish layer is only applied to a partial region of the surface of the base body.

In this way, motifs over part of the surface can be generated which supplement other graphic or design elements of the base body.

It is also possible if an etch resist is applied to a partial region of the first varnish layer and/or the at least one further layer and the first varnish layer and/or the at least one further layer is removed where it is not covered by the etch resist.

Motifs over part of the surface can thus also be generated. The etch resist is preferably acrylate, polyester, epoxy, polyurethane resins or acrylate copolymers with a layer thickness of from 0.1 μm to 10 μm, preferably from 0.1 μm to 5 μm.

To remove the first varnish layer and/or the at least one further layer, as described, an acidic sodium metaperiodate solution can be used under the above-named conditions.

It is furthermore advantageous if the exposure is effected from the side of the base body.

Structures of the base body which are not or are only partially transparent for the exposure wavelength can act as internal exposure mask. An external mask is thus not necessary, with the result that the problems associated with the use of an external mask with respect to the arrangement of the mask and the resulting register accuracy do not arise.

By register accuracy is meant a positional accuracy of two or more elements and/or layers relative to each other. The register accuracy is to vary within a predefined tolerance and to be as low as possible. At the same time, the register accuracy of several elements and/or layers relative to each other is an important feature for increasing the protection against forgery. The positionally accurate positioning can in particular be effected by means of optically detectable registration marks or register marks. These registration marks or register marks can either represent special separate elements or regions or layers or themselves be part of the elements or regions or layers to be positioned. A “perfect register” is referred to when the register tolerance is close to zero or practically zero.

In particular, it is expedient if the base body comprises at least one partial layer, in particular a fourth varnish layer and/or a reflective layer, which in the first region is transparent for a wavelength range used for the exposure of the first varnish layer and in the second region is non-transparent for a wavelength range used for the exposure of the first varnish layer.

During the exposure of the first varnish layer, the latter is thus exposed precisely registered relative to this partial layer. The unexposed regions are congruent with the non-transparent regions of the partial layer and the exposed regions are congruent with the transparent regions of the partial layer. By “congruent” is meant an exact covering when viewed in the direction of the surface normals to the respective layers.

By a transparent region is meant a region which has a transmissivity of at least 50%, preferably at least 70%, in the respective wavelength range.

By a non-transparent region is meant a region which has a transmissivity of at most 30%, preferably at most 20%, in the respective wavelength range.

It is preferred if the difference or the contrast between the transmissivity of the transparent region and that of the non-transparent region is at least 2, in particular at least 5.

The exposure is preferably effected at a wavelength of from 350 nm to 400 nm with an exposure time of from 0.1 s to 120 s, preferably from 0.1 s to 60 s, and/or an exposure dose of from 1 mJ/cm² to 300 mJ/cm², preferably from 1 mJ/cm² to 100 mJ/cm². Compared with the case of the exposure of solvent-based photoresists, particularly gentle exposure with low intensity is thus possible.

Further preferably, to remove the first varnish layer in the second region, water with added isopropanol, in particular with 0.1% to 50% isopropanol, preferably with 5% isopropanol, is used.

As already explained at the beginning, a gentle removal of the unexposed photoresist layer is thus possible during which further layers of the base body are not attacked.

It is expedient if, for the application of the first varnish layer, an aqueous photoresist is used which contains at least one water-soluble polymer, at least one film-forming polymer, at least one additive and at least one photoinitiator.

The water-soluble polymer is preferably selected from the group: arginic acid derivatives, cellulose derivatives and/or carboxylated acrylic polymers such as e.g. sodium carboxymethyl cellulose methyl cellulose, polyvinyl alcohol resins, polyethylene oxide, homo- and/or copolymeric vinyl acetates, polyacrylamides, long-chain carboxylic acids.

The water-soluble polymer ensures the detachability of the unexposed photoresist by aqueous solvents and improves its dispersibility.

The water-soluble polymer is preferably contained in the aqueous photoresist in a concentration of from 1 wt.-% to 50 wt.-%, preferably from 1 wt.-% to 20 wt.-%.

It is further preferred if the film-forming polymer is selected from the group: polyvinyl acetate resins, ethylene-vinyl acetate copolymers, vinyl acetate-acrylate copolymers, acrylic copolymers, polyurethane copolymers, polyacrylates, polyurethanes, polyester and/or epoxy resins, polyvinylpyrrolidone, urethane acrylate.

The film-forming polymer is dispersed in the varnish and forms the actual matrix of the varnish after exposure and drying.

It is preferred if the film-forming polymer is contained in the aqueous photoresist in a concentration of from 1 wt.-% to 50 wt.-%, preferably from 10 wt.-% to 30 wt.-%.

In order to improve the dispersibility and stability of the varnish, it is expedient if the at least one additive is or comprises a dispersing additive, which is contained in the aqueous photoresist in a concentration of from 0.1 wt.-% to 5 wt.-%, preferably from 0.1 wt.-% to 3 wt.-%.

Furthermore it is advantageous if the at least one additive is or comprises a defoamer, which is contained in the aqueous photoresist in a concentration of from 0.1 wt.-% to 5% wt.-%, preferably from 0.1 wt.-% to 3 wt.-%. The processability of the varnish is hereby improved.

It is further preferred if the photoinitiator is or comprises a photosensitive diazo resin, in particular a 4-diazodiphenylamine/formaldehyde condensate, which is contained in the aqueous photoresist in a concentration of from 0.1 wt.-% to 5 wt.-%, preferably from 0.1 wt.-% to 3 wt.-%.

During UV irradiation such diazo resins act as crosslinkers which link the polymer chains of the varnish in the exposed regions together. The increase in the molecular weight associated therewith results in a decrease in the water solubility, with the result that the exposed varnish is not washed off during developing.

It is furthermore preferred if the aqueous photoresist contains 1% to 30%, preferably 5% to 15%, isopropanol.

It is particularly preferred if the first and/or second and/or third and/or fourth varnish layer comprises colorants, in particular multi-colored or achromatic pigments and/or effect pigments, UV-excitable fluorescent pigments, thin-film systems, cholesteric liquid crystals, dyes and/or metallic or non-metallic nanoparticles. A plurality of appealing optical effects can hereby be realized.

In particular, it is expedient if the first and/or second and/or third and/or fourth varnish layer each comprise different colorants.

If the respective varnish layers are structured registered relative to each other in the above-described manner, appealing multi-colored designs are thus obtained which have a higher resolution and register accuracy than comparable printed structures.

It is advantageous if the first and/or second and/or third and/or fourth varnish layer is applied and/or structured in the form of a graphic motif, alphanumeric character, logo, image, pattern, in particular guilloche pattern.

Combinations of the named design elements are also possible.

It is furthermore preferred if the first varnish layer is applied to a base body which comprises one or more of the following layers: a carrier ply, a wax layer, a detachment layer, a protective layer, a replication layer with a surface relief, a reflective layer, a volume hologram layer, a colored varnish layer, a base coat layer.

Further design, security and functional elements can hereby be integrated into the multilayer body, with the result that an optically particularly appealing and very processable multilayer body with particularly good protection against forgery is obtained.

The carrier ply forms a stable base ply, on which the further layer composite can be built up, and preferably consists of polyester, polyolefin, polyvinyl, polyimide, ABS. Particularly preferably of PET, PC, PP, PE, PVC, PS with a layer thickness of from 4 μm to 75 μm, preferably from 6 μm to 50 μm, further preferably from 9 μm to 26 μm.

A detachment layer is preferably arranged between the carrier ply and further layers of the base body and preferably consists of wax or silicone with a layer thickness of from 0.005 μm to 0.3 μm, preferably from 0.01 μm to 0.1 μm. The detachment layer can alternatively also consist of a strongly filming acrylate polymer/copolymer and/or also be part of the protective varnish layer and have a layer thickness of from 1 μm to 5 μm, preferably 1 μm to 3 μm. The detachment layer makes it possible to detach the carrier ply without trouble when the multilayer body is transferred to a security document.

A base coat layer preferably forms the surface of the base body, to which the first varnish layer is applied, and serves to promote adhesion for the first varnish layer. The base coat layer preferably consists of polyester, epoxide, polyurethane, acrylate and/or copolymer resins or mixtures thereof, with a layer thickness of from 0.5 μm to 15 μm, preferably from 1 μm to 5 μm, further preferably from 1 μm to 3 μm. Alternatively, thermoplastic adhesives, hot waxes, UV-curable adhesives or cold adhesives, or self-adhesive adhesives, can also be used.

Replication layers serve to generate optically variable effects, for example surface holograms. The replication layer preferably consists of acrylates or acrylate copolymers such as urethane acrylates, polyester acrylates, epoxy acrylates or acrylate copolymers, polyester acrylates, with a layer thickness of from 0.1 μm to 50 μm, preferably from 0.2 μm to 5 μm. The replication layers can be thermoplastically structurable and/or also radiation-curable, in particular by means of UV radiation.

Reflective layers serve to improve the visibility of such optically variable effects and can also be used to realize further design effects.

It can be a metal layer, in particular made of aluminum, copper, silver, gold, chromium or an alloy of the above-named metals. Alternatively, the reflective layer can also be formed as a layer made of a high refractive index (HRI) material, in particular made of zinc sulfide or titanium dioxide.

The layer thickness of a metallic reflective layer is preferably from 5 nm to 150 nm, particularly preferably from 10 nm to 50 nm. The layer thickness of HRI layers is preferably from 30 nm to 250 nm. In the thickness range from 30 nm to 75 nm a more color-neutral reflection results, while in the case of thicker layers the light reflected by the reflective layer displays pronounced colors.

Protective layers can be used in order to form an outer surface of the multilayer body that is stable vis-à-vis environmental influences. Preferred varnishes for this are polyacrylates, acrylate compounds and/or polymethacrylates, epoxides, polyvinylidene fluorides with a layer thickness of from 1 μm to 10 μm, preferably from 1 μm to 5 μm.

Volume hologram layers likewise serve to generate optically variable effects and typically consist of a monomer, an initiator and a photosensitive dye. They preferably contain substances from the following groups: acrylates, amides, epoxides, vinyl esters, vinyl ethers, styrenes, polyols, polyisocyanates, acrylamides, polyvinyl alcohol, polyurethanes, with a layer thickness of from 3 μm to 50 μm, preferably from 5 μm to 25 μm.

It is furthermore preferred if the surface relief introduced into the replication layer forms an optically variable element, in particular a hologram, Kinegram® or Trustseal®, a preferably linear or crossed sinusoidal diffraction grating, a linear or crossed single- or multi-step rectangular grating, a zero-order diffraction structure, an asymmetrical relief structure, a blazed grating, a preferably isotropic or anisotropic mat structure, or a light-diffracting and/or light-refracting and/or light-focusing micro- or nanostructure, a binary or continuous Fresnel lens, a binary or continuous Fresnel free-form surface, a microprism structure or a combined structure thereof.

A plurality of appealing optically variable effects with protection against forgery can hereby be generated.

The invention is now explained in more detail with reference to embodiment examples. There are shown in

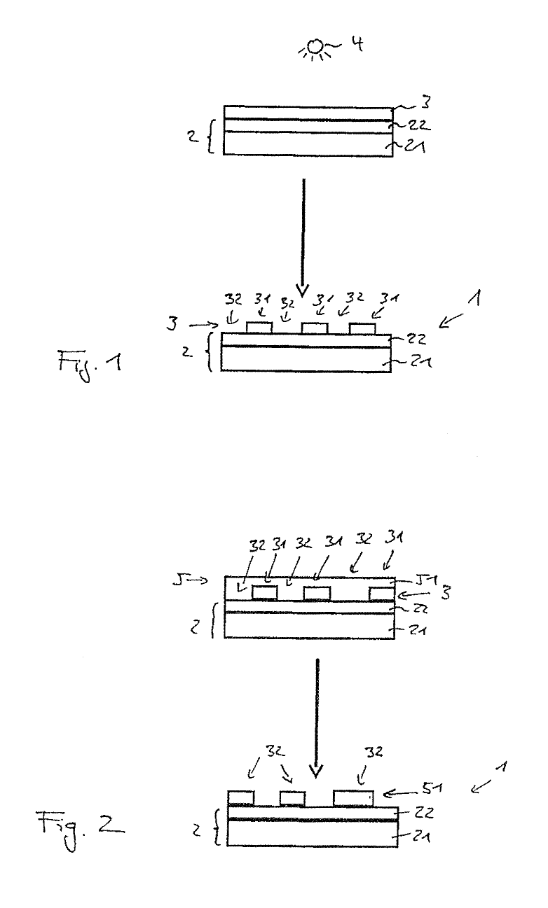

FIG. 1 a schematic representation of the method steps during the production of an embodiment example of a multilayer body with a structured layer made of a water-based photoresist;

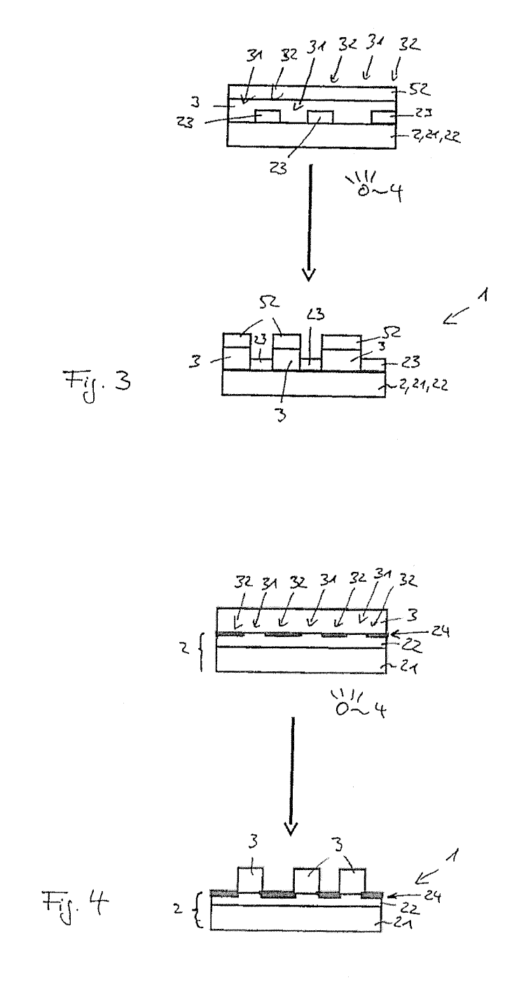

FIG. 2 a schematic representation of the method steps during the production of an alternative embodiment example of a multilayer body using a water-based photoresist as wash varnish for a further varnish layer;

FIG. 3 a schematic representation of the method steps during the production of a further alternative embodiment example of a multilayer body with a structured layer made of a water-based photoresist using a partial varnish layer as internal exposure mask;

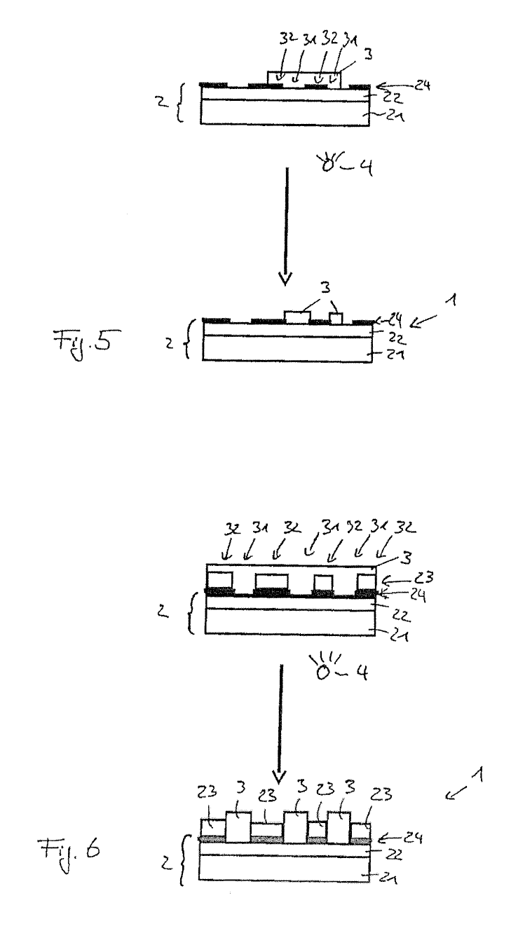

FIG. 4 a schematic representation of the method steps during the production of a further alternative embodiment example of a multilayer body with a structured layer made of a water-based photoresist using a partial metal layer as internal exposure mask;

FIG. 5 a schematic representation of the method steps during the production of a further alternative embodiment example of a multilayer body with a structured partial layer made of a water-based photoresist using a partial metal layer as internal exposure mask;

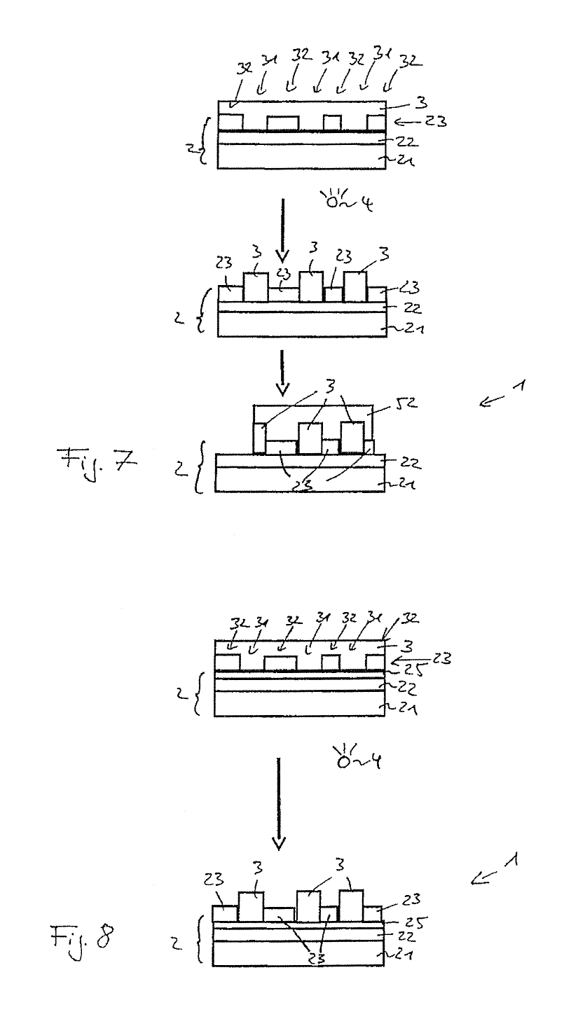

FIG. 6 a schematic representation of the method steps during the production of a further alternative embodiment example of a multilayer body with a structured layer made of a water-based photoresist using a partial metal layer and partial varnish layer as internal exposure mask;

FIG. 7 a schematic representation of the method steps during the production of a further alternative embodiment example of a multilayer body with a structured layer made of a water-based photoresist using a partial varnish layer as internal exposure mask and subsequent structuring by an etch resist;

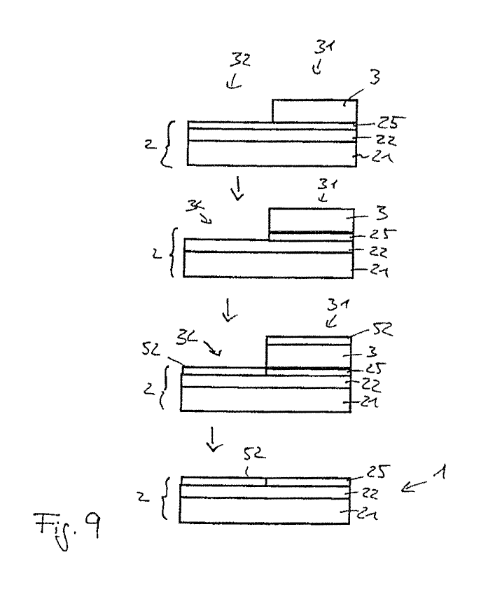

FIG. 8 a schematic representation of the method steps during the production of a further alternative embodiment example of a multilayer body with a structured layer made of a water-based photoresist using a partial varnish layer as internal exposure mask;

FIG. 9 a schematic representation of the method steps during the production of an alternative embodiment example of a multilayer body using a water-based photoresist as wash varnish to generate two complementary reflective layers;

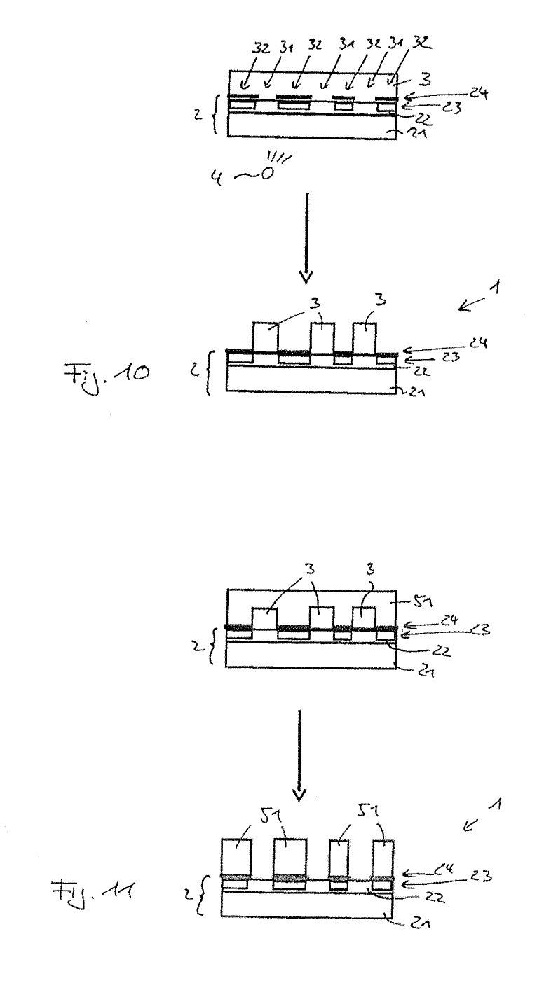

FIG. 10 a schematic representation of the method steps during the production of a further alternative embodiment example of a multilayer body with a structured layer made of a water-based photoresist using a partial metal layer and partial varnish layer as internal exposure mask;

FIG. 11 a schematic representation of the method steps during the further processing of the multilayer body according to FIG. 10 using the water-based photoresist as wash varnish to structure a further colored varnish layer.

During the production of a multilayer body 1, a base body 2 is first provided which has a carrier ply 21 and a layer composite 22. On the side of the base body 2 facing away from the carrier ply 21, a first varnish layer 3 made of a water-based photoresist is deposited and exposed by means of a mask, not represented in FIG. 1.

The light from a UV light source 4 only strikes partial regions 31 of the first varnish layer 3 which are not shaded by the mask. The partial regions 32 shaded by the mask, in contrast, are not exposed. When the first varnish layer 3 is then developed, the exposed varnish in the partial regions 31 remains, while the varnish in the partial regions 32 is removed by the developing agent.

The structure of the base body 2 outlined below applies to all of the embodiments described in the following.

The carrier ply 21 forms a stable base ply on which the further layer composite 22 can be built up and preferably consists of polyester, polyolefin, polyvinyl, polyimide, ABS. Particularly preferably of PET, PC, PP, PE, PVC, PS with a layer thickness of from 4 μm to 75 μm, preferably from 6 μm to 50 μm, further preferably from 9 μm to 25 μm.

The layer composite 22 can comprise one or more of the following layers: a carrier ply, a wax layer, a detachment layer, a protective layer, a replication layer with a surface relief, a reflective layer, a volume hologram layer, a colored varnish layer, a base coat layer.

A detachment layer is preferably arranged between the carrier ply 21 and further layers of the base body 2 and preferably consists of wax or silicone with a layer thickness of from 0.0005 μm to 0.3 μm, preferably from 0.01 μm to 0.1 μm. The detachment layer can alternatively also consist of a strongly filming acrylate polymer/copolymer and/or also be part of the protective varnish layer and have a layer thickness of from 1 μm to 5 μm, preferably 1 μm to 3 μm. The detachment layer makes it possible to detach the carrier ply 21 without trouble when the multilayer body 1 is transferred to a security document.

A base coat layer preferably forms the surface of the base body 2, to which the first varnish layer 3 is applied, and serves to promote adhesion for the first varnish layer 3. The base coat layer preferably consists of polyester, epoxide, polyurethane, acrylate and/or copolymer resins or mixtures thereof, with a layer thickness of from 1 μm to 5 μm, preferably from 1 μm to 3 μm. Alternatively, thermoplastic adhesives, hot waxes, UV-curable adhesives or cold adhesives, or self-adhesive adhesives, can also be used.

Replication layers serve to generate optically variable effects, for example surface holograms. The replication layer preferably consists of acrylates or acrylate copolymers such as urethane acrylates, polyester acrylates, epoxy acrylates or acrylate copolymers, polyester acrylates, with a layer thickness of from 0.1 μm to 50 μm, preferably from 0.2 μm to 5 μm.

A surface relief which forms an optically variable element, in particular a hologram, Kinegram® or Trustseal®, a preferably linear or crossed sinusoidal diffraction grating, a linear or crossed single- or multi-step rectangular grating, a zero-order diffraction structure, an asymmetrical relief structure, a blazed grating, a preferably isotropic or anisotropic mat structure, or a light-diffracting and/or light-refracting and/or light-focusing micro- or nanostructure, a binary or continuous Fresnel lens, a binary or continuous Fresnel free-form surface, a microprism structure or a combined structure thereof, can be introduced into the replication layer.

Reflective layers serve to improve the visibility of such optically variable effects and can also be used to realize further design effects.

It can be a metal layer, in particular made of aluminum, copper, silver, gold, chromium or an alloy of the above-named metals. Alternatively, the reflective layer can also be formed as a layer made of a high refractive index (HRI) material, in particular made of zinc sulfide or titanium dioxide.

The layer thickness of a metallic reflective layer is preferably from 5 nm to 150 nm, particularly preferably from 10 nm to 50 nm. The layer thickness of HRI layers is preferably from 30 nm to 250 nm. In the thickness range from 30 nm to 75 nm a more color-neutral reflection results, while in the case of thicker layers the light reflected by the reflective layer displays pronounced colors.

Protective layers can be used in order to form an outer surface of the multilayer body that is stable vis-à-vis environmental influences. Preferred varnishes for this are polyacrylates, acrylate compounds and/or polymethacrylates, epoxides, polyvinylidene fluorides with a layer thickness of from 1 μm to 10 μm, preferably from 1 μm to 5 μm.

Volume hologram layers likewise serve to generate optically variable effects and typically consist of a monomer, an initiator and a photosensitive dye. They preferably contain substances from the following groups: acrylates, amides, epoxides, vinyl esters, vinyl ethers, styrenes, polyols, polyisocyanates, acrylamides, polyvinyl alcohol, polyurethanes, with a layer thickness of from 3 μm to 50 μm, preferably from 5 μm to 25 μm.

Colored varnish layers of the layer composite 22 can be solvent-based and have a preferred layer thickness of from 0.1 μm to 10 μm, particularly preferably from 0.2 μm to 5 μm. The colored varnish layers are dyed by means of pigments and/or dyes. The pigments and/or dyes can display a color effect in visible light, but also alternatively or additionally also in infrared light (IR light) and/or in ultraviolet light (UV light). By means of optically variable pigments, the colored varnish layers can also have optically variable effects.

The first varnish layer 3 preferably consists of an aqueous photoresist which contains at least one water-soluble polymer, at least one film-forming polymer, at least one additive and at least one photoinitiator.

A corresponding composition of the varnish of the first varnish layer 3 applies to all of the embodiment examples described.

The water-soluble polymer is preferably selected from the group: arginic acid derivatives, cellulose derivatives and/or carboxylated acrylic polymers such as e.g. sodium carboxymethyl cellulose methyl cellulose, polyvinyl alcohol resins, polyethylene oxide, homo- and/or copolymeric vinyl acetates, polyacrylamides, long-chain carboxylic acids.

The water-soluble polymer ensures the detachability of the unexposed photoresist by aqueous solvents and improves its dispersibility.

The water-soluble polymer is preferably contained in the aqueous photoresist in a concentration of from 1 wt.-% to 50 wt.-%, preferably from 1 wt.-% to 20 wt.-%.

It is further preferred if the film-forming polymer is selected from the group: polyvinyl acetate resins, ethylene-vinyl acetate copolymers, vinyl acetate-acrylate copolymers, acrylic copolymers, polyurethane copolymers, polyacrylates, polyurethanes, polyester and/or epoxy resins, polyvinylpyrrolidone, urethane acrylate.

The film-forming polymer is dispersed in the varnish and forms the actual matrix of the varnish after exposure and drying.

It is preferred if the film-forming polymer is contained in the aqueous photoresist in a concentration of from 1 wt.-% to 50 wt.-%, preferably from 10 wt.-% to 30 wt.-%.

In order to improve the dispersibility and stability of the varnish, it is expedient if the at least one additive is or comprises a dispersing additive, which is contained in the aqueous photoresist in a concentration of from 0.1 wt.-% to 5 wt.-%, preferably from 0.1 wt.-% to 3 wt.-%.

Furthermore it is advantageous if the at least one additive is or comprises a defoamer, which is contained in the aqueous photoresist in a concentration of from 0.1 wt.-% to 5 wt.-%, preferably from 0.1 wt.-% to 3 wt.-%. The processability of the varnish is hereby improved.

It is further preferred if the photoinitiator is or comprises a photosensitive diazo resin, in particular a 4-diazodiphenylamine/formaldehyde condensate, which is contained in the aqueous photoresist in a concentration of from 0.1 wt.-% to 5 wt.-%, preferably from 0.1 wt.-% to 3 wt.-%.

During UV irradiation such diazo resins act as crosslinkers which link the polymer chains of the varnish in the exposed regions together. The increase in the molecular weight associated therewith results in a decrease in the water solubility, with the result that the exposed varnish is not washed off during developing.

It is furthermore preferred if the aqueous photoresist contains 1% to 30%, preferably 5% to 15%, isopropanol.

The first varnish layer 3 furthermore preferably comprises colorants, in particular multi-colored or achromatic pigments and/or effect pigments, UV-excitable fluorescent pigments, thin-film systems, cholesteric liquid crystals, dyes and/or metallic or non-metallic nanoparticles. These pigments and/or dyes can display a color effect in visible light, but also alternatively or additionally also in infrared light (IR light) and/or in ultraviolet light (UV light). By means of optically variable pigments, the colored varnish layers can also have optically variable effects.

Examples of varnish formulations are given in the following tables:

| Varnish formulation 1 | Wt.-% |
|---|---|
| Polyvinyl alcohol | 1.6 |
| Polyvinylpyrrolidone | 13.4 |
| Diazodiphenylamine/formaldehyde-condensate- | 0.45 |
| hydrogen sulfate (complexed with zinc chloride) | |
| Dispersing additive, e.g. Disperbyk 190 | 0.25 |
| Defoamer, e.g. BYK 012 | 0.125 |
| Isopropanol | 9.55 |
| Water | 74.625 |

| Varnish formulation 1 (colored) | Wt.-% |
|---|---|
| Polyvinyl alcohol | 1.6 |
| Polyvinylpyrrolidone | 13.4 |
| Diazodiphenylamine/formaldehyde-condensate- | 0.45 |
| hydrogen sulfate (complexed with zinc chloride) | |
| Dispersing additive, e.g. Disperbyk 190 | 0.25 |
| Defoamer, e.g. BYK 012 | 0.125 |
| Isopropanol | 9.55 |
| Water | 69.025 |
| Dye dispersion or dye (e.g. iron oxide, Luconyl | 5.6 |
| NG) | |

| Varnish formulation 2 | Wt.-% |
|---|---|
| Aliphatic urethane acrylate oligomer | 20 |
| Water-soluble diacrylate monomer | 2 |
| Diazodiphenylamine/formaldehyde-condensate- | 0.62 |
| hydrogen sulfate (complexed with zinc chloride) | |
| Dispersing additive, e.g. Disperbyk 190 | 0.25 |
| Defoamer, e.g. BYK 012 | 0.13 |
| Water | 77 |

The exposure of the first varnish layer 3 is preferably effected at a wavelength of from 350 nm to 400 nm with an exposure time of from 0.1 s to 120 s, preferably from 0.1 s to 60 s, and/or an exposure dose of from 1 mJ/cm² to 300 mJ/cm², preferably from 1 mJ/cm² to 100 mJ/cm².

In particular, UV LEDs can be used as UV light source 4. Also suitable are mercury-vapor lamps, which can also be doped, such as for example with gallium or iron, in order to match the radiation spectrum to the sensitivity of the photoactivator and the transmitting behavior of the varnish layers.

Furthermore, lasers can also be used for the exposure. Because of their beam quality, they can also be used for controlled partial exposure through the medium of a deflection unit and thus, for example, carry out an individual exposure.

During the exposure, the photoactivator is activated and acts as crosslinker for the polymer chains of the varnish in the region 31, with the result that its water solubility is lost there.

For the developing, thus for the removal of the first varnish layer 3 in the second region 32, water with added isopropanol, in particular with 1% to 30% isopropanol, preferably with 5% isopropanol, can then preferably be used, with the result that a gentle removal of the unexposed regions 32 is made possible, without other layers of the layer composite 22 being attacked.

In order to ensure the bonding or a sufficient adhesion of the first varnish layer 3 or further layers, a pretreatment, e.g. by means of corona or plasma, can be carried out before the application.

As FIG. 2 shows, after the exposure and developing of the first varnish layer 3, a further layer composite 5 can be applied to it. In the embodiment example according to FIG. 2 this is only one individual varnish layer 51 made of a colored varnish.

The varnish layer 51 furthermore preferably comprises colorants, in particular multi-colored or achromatic pigments and/or effect pigments, UV-excitable fluorescent pigments, thin-film systems, cholesteric liquid crystals, dyes and/or metallic or non-metallic nanoparticles. These pigments and/or dyes can display a color effect in visible light, but also alternatively or additionally also in infrared light (IR light) and/or in ultraviolet light (UV light). By means of optically variable pigments, the colored varnish layers can also have optically variable effects.

The layer thickness of the varnish layer 51 is preferably from 0.1 μm to 10 μm, particularly preferably from 1 μm to 5 μm.

The first varnish layer 3 is removed again after the varnish layer 51 has been deposited. The aqueous photoresist of the first varnish layer 3 here thus acts as wash varnish. Not only the first varnish layer 3, but with it also the varnish layer 51 is removed in the regions 31, with the result that they remain only in the regions 32.

It is preferred in particular if the first varnish layer 31 and the varnish layer 51 are removed by treatment with an acidic sodium metaperiodate solution, in particular an aqueous solution of 1.5 wt.-% sodium metaperiodate and 0.05 wt.-% sulfuric acid.

The removal of the first varnish layer 31 is thus an oxidative process. The admixture of acid serves to stabilize the metaperiodate. Instead of sulfuric acid, nitric acid can also be used for example.

The pH of the sodium metaperiodate solution is preferably from 1 to 7, particularly preferably from 2 to 5.

The treatment with the acidic sodium metaperiodate solution is preferably effected at a temperature of from 15° C. to 70° C., preferably from 25° C. to 50° C., and/or with a treatment duration of from 600 s to 1 s, preferably from 120 s to s.

The detachment of the first varnish layer 31 can furthermore be supported by agitation of the solution, targeted flow against the multilayer body, brushing, smearing or sonication.

Furthermore, it is expedient if a non-ionic surfactant is added to the acidic sodium metaperiodate solution, in particular selected from the group ethoxylate, alkoxylates of primary or secondary fatty alcohols, alkyl phenols, ethylene oxide/propylene oxide copolymers, amine ethoxylates, alkyl polyglycolides, fatty amine oxides, fatty acid alkanolamides, fatty acid alkyl glucamides.

Such surfactants act as wetting agents and ensure that the sodium metaperiodate solution completely wets the first varnish layer 31 and the varnish layer 51, with the result that the desired detachment result can be achieved.

The concentration of the surfactant is preferably from 0% to 50%, particularly preferably from 0.01% to 3%.

In the embodiment according to FIG. 3, the base body 22 comprises a partial varnish layer 23. This is non-transparent for the wavelength range used for the exposure of the first varnish layer 3, thus preferably has a transmissivity of less than 20% in this wavelength range.

Furthermore, a metal layer 52 is applied to the first varnish layer 3 before the exposure and developing of the first varnish layer 3. It consists in particular of aluminum, copper, silver, gold, chromium or an alloy of the above-named metals with a layer thickness of from 1 nm to 1 μm, preferably from 10 nm to 100 nm.

The exposure of the first varnish layer 3 in this case is effected from the side of the base body 2. The first varnish layer 3 is exposed in the regions 31 where the partial varnish layer 23 is not present; no exposure is effected in the regions 32 where the partial varnish layer 23 is present, with the result that during the subsequent developing of the partial varnish layer 3 the latter is removed together with the metal layer 52 in the regions 32. The partial varnish layer 3 and the metal layer 52 thus form a motif that complements the partial varnish layer 23.

In the embodiment according to FIG. 4, the base body 22 comprises a partial metal layer 24. Analogously to the partial varnish layer 23 according to FIG. 3, this is non-transparent for the wavelength range used for the exposure of the first varnish layer 3.

The partial metal layer 24 consists in particular of aluminum, copper, silver, gold, chromium or an alloy of the above-named metals with a layer thickness of from 1 nm to 1 μm, preferably from 10 nm to 100 nm.

The exposure of the first varnish layer 3 here is also effected from the side of the base body 2. The first varnish layer 3 is exposed in the regions 31 where the partial metal layer 24 is not present; no exposure or only a slight exposure is effected in the regions 32 where the partial metal layer 24 is present, with the result that during the subsequent developing of the partial varnish layer 3 the latter is removed in the regions 32. The first varnish layer 3 thus forms a motif that complements the partial metal layer 24.

The embodiment example according to FIG. 5 corresponds to that according to FIG. 4, and only differs in that the first varnish layer 31 is applied to the base body 2 not over the whole surface, but only partially.

The embodiment example according to FIG. 6 also corresponds to that according to FIG. 4, and only differs in that, in addition to the partial metal layer 24, the base body has a partial varnish layer 23 which is congruent with the partial metal layer 24 in the direction of the surface normals to the plane of extension of the base body.

The embodiment example according to FIG. 7 corresponds to the embodiment example according to FIG. 3. However, the application of the metal layer 51 to the first varnish layer 3 is dispensed with. Here too, the first varnish layer 3 is exposed from the side of the base body 2 using a partial varnish layer 23 of the base body 2 as internal mask, and then developed as described.

In a further step, an etch resist 53 is now applied partially to the first varnish layer 3 and the partial varnish layer 23. The first varnish layer 3 and the partial varnish layer 23 are then removed where they are not covered by the etch resist 53.

The etch resist 53 preferably consists of acrylate, polyester, epoxy, polyurethane resins or acrylate copolymers with a layer thickness of from 0.1 μm to 10 μm, preferably from 0.1 μm to 5 μm.

The etch resist 53 can also be applied in the form of a pattern, grid or motif, in particular also in the form of a fine line pattern, which, in the resulting multilayer body 1, is then dyed in the color pattern of the first varnish layer 3 and the partial varnish layer 23.

The embodiment according to FIG. 8 also corresponds to the embodiment example according to FIG. 3. A structuring of the first varnish layer 3 using the partial varnish layer 23 as internal mask is likewise effected here. Unlike in FIG. 3, here only one further reflective layer 25 over the whole surface is provided in the base body 2, which has the properties explained at the beginning in the description of the base body 2.

Here too, analogously to FIG. 7, a further structuring by application of an etch resist 53 and subsequent etching can then be effected.

In the embodiment example according to FIG. 9, the first varnish layer 3 is used as wash varnish, analogously to FIG. 2. In this embodiment, the first varnish layer 3 is first deposited on a reflective layer 25 of the base body 2, exposed by means of an external mask or a laser and removed in the unexposed region 32 during the developing.

An etching step in which the reflective layer 25 is removed in the region 32 is then effected. During the etching, the reflective layer is protected in the region 31 by the first varnish layer 3, with the result that it remains there.

A further reflective layer 52 is then applied to the base body 2 and the first varnish layer 3, for example by vapor deposition, sputtering, chemical vapor deposition or the like.

During a subsequent treatment with sodium metaperiodate solution, the first varnish layer 3 is removed together with the further reflective layer 52 in the first region 31. The reflective layer 25 now remains there on the surface of the base body 2, while the further reflective layer 52 forms the surface of the base body in the first region 31. This makes sense in particular if different materials are used for the reflective layers 25, 52. Thus, for example, two different metals or metal alloys can be arranged complementary to each other.

Here too, a partial overprinting with an etch resist and a further structuring of the reflective layers 25, 52 can then be effected.

The embodiment according to FIG. 10 is analogous to the embodiment according to FIG. 6. Here too, a partial metal layer 24 and a partial varnish layer 23 are used as internal exposure mask for the first varnish layer 3. The only difference is in the layer sequence. Here, the partial metal layer 24 faces the first varnish layer 3, while the partial varnish layer 23 faces the carrier ply 21.

This layer sequence makes it possible to structure the partial metal layer 24 likewise using the partial varnish layer 23. For this, the partial varnish layer 23 is first generated and then the metal layer 24 is applied over the whole surface. A photosensitive etch resist which is exposed through the base body 2 is deposited on the metal layer 24. When a positive resist is used, the resist remains, after the developing, overlapping with the partial varnish layer 23, with the result that during the subsequent etching the partial metal layer 24 also remains precisely registered congruent with the partial varnish layer 23.

After removal of the resist, as already described with reference to FIG. 6, the first varnish layer 3 can then be generated precisely registered complementary to the layers 23, 24.

Starting from the thus-generated layer structure, as shown in FIG. 11, a further colored varnish layer 51 can be applied. Analogously to FIG. 2, the first varnish layer 3 is then removed by acidic sodium metaperiodate solution. The further colored varnish layer 51 is also removed in the regions in which the first varnish layer 3 is present, with the result that it now remains precisely registered congruent with the partial varnish layer 23 and the partial metal layer 24.

### LIST OF REFERENCE NUMBERS

1 multilayer body
2 base body
21 carrier ply
22 layer composite
23 partial varnish layer
24 partial metal layer
25 reflective layer
3 first varnish layer
31 exposed region
32 unexposed region
4 UV light source
5 further layer composite
51 colored varnish layer
52 reflective layer
53 etch resist

1. A method for producing a multilayer body comprising:
a) applying a first varnish layer made of a water-based photoresist to a surface of a base body;
b) exposing the first varnish layer in a first region, wherein the first varnish layer is not exposed in a second region; and
c) removing the first varnish layer in the second region.

2. The method according to claim 1, wherein the base body comprises at least one second varnish layer made of a solvent-based varnish.

3. The method according to claim 1, wherein the first varnish layer is applied to a surface of the second varnish layer.

4. The method according to claim 1, wherein at least one further layer is applied to the first varnish layer.

5. The method according to claim 4, wherein, after the application of the at least one further layer, the first varnish layer and the at least one further layer are removed in the first region.

6. The method according to claim 5, wherein the first varnish layer and the at least one further layer are removed by treatment with an acidic sodium metaperiodate solution.

7. The method according to claim 6, wherein the treatment with the acidic sodium metaperiodate solution is effected at a temperature of from 15° C. to 70° C., and/or with a treatment duration of from 600 s to 1 s.

8. The method according to claim 6 wherein a non-ionic surfactant is added to the acidic sodium metaperiodate solution, the non-ionic surfactant being selected from the group ethoxylate, alkoxylates of primary or secondary fatty alcohols, alkyl phenols, ethylene oxide/propylene oxide copolymers, amine ethoxylates, alkyl polyglycolides, fatty amine oxides, fatty acid alkanolamides, fatty acid alkyl glucamides.

9. The method according to claim 4, wherein the at least one further layer is or comprises a third varnish layer, made of a solvent-based varnish.

10. The method according to claim 4, wherein the at least one further layer is comprises a reflective layer.

11. The method according to claim 10, wherein the first varnish layer is applied to a reflective layer of the base body and, before the application of the at least one further layer, the reflective layer of the base body is removed in the first region, by etching.

12. The method according to claim 1, wherein the first varnish layer is only applied to a partial region of the surface of the base body.

13. The method according to claim 1, wherein an etch resist is applied to a partial region of the first varnish layer and/or of the at least one further layer and the first varnish layer and/or the at least one further layer is removed where it is not covered by the etch resist.

14. The method according to claim 1, wherein the exposure is effected from the side of the base body.

15. The method according to claim 14, wherein the base body comprises at least one partial layer, which in the first region is transparent for a wavelength range used for the exposure of the first varnish layer and in the second region is non-transparent for a wavelength range used for the exposure of the first varnish layer.

16. The method according to claim 1, wherein the exposure is effected at a wavelength of from 350 nm to 400 nm with an exposure time of from 0.1 s to 120 s, and/or an exposure dose of from 1 mJ/cm² to 300 mJ/cm².

17. The method according to claim 1, wherein, to remove the first varnish layer in the second region, a water with added isopropanol, is used.

18. The method according to claim 1, wherein, for the application of the first varnish layer, an aqueous photoresist is used which contains at least one water-soluble polymer, at least one film-forming polymer, at least one additive and at least one photoinitiator.

19. The method according to claim 18, wherein the water-soluble polymer is selected from the group: arginic acid derivatives, cellulose derivatives and/or carboxylated acrylic polymers such as e.g. sodium carboxymethyl cellulose, methyl cellulose, polyvinyl alcohol resins, polyethylene oxide, homo- and/or copolymeric vinyl acetates, polyacrylamides, long-chain carboxylic acids.

20. The method according to claim 18 wherein the water-soluble polymer is contained in the aqueous photoresist in a concentration of from 1 wt.-% to 50 wt. %, preferably from 1 wt. % to 20 wt. %.

21. The method according to claim 18, wherein the film-forming polymer is selected from the group: polyvinyl acetate resins, ethylene-vinyl acetate copolymers, vinyl acetate-acrylate copolymers, acrylic copolymers, polyurethane copolymers, polyacrylates, polyurethanes, polyester and/or epoxy resins, polyvinylpyrrolidone, urethane acrylate.

22. The method according to claim 18, wherein the film-forming polymer is contained in the aqueous photoresist in a concentration of from 1 wt.-% to 50 wt. %.

23. The method according to claim 18, wherein the at least one additive is comprises a dispersing additive, which is contained in the aqueous photoresist in a concentration of from 0.1 wt.-% to 5 wt. %.

24. The method according to claim 18, wherein the at least one additive comprises a defoamer, which is contained in the aqueous photoresist in a concentration of from 0.1 wt.-% to 5 wt-%.

25. The method according to claim 18, wherein the photoinitiator comprises a 4-diazodiphenylamine/formaldehyde condensate, which is contained in the aqueous photoresist in a concentration of from 0.1 wt.-% to 5 wt.-%.

26. The method according to claim 18, wherein the aqueous photoresist contains 1% to 30% isopropanol.

27. The method according to claim 1, wherein the first and/or second and/or third and/or fourth varnish layer comprises multi-colored or achromatic pigments and/or effect pigments, UV-excitable fluorescent pigments, thin-film systems, cholesteric liquid crystals, dyes and/or metallic or non-metallic nanoparticles.

28. The method according to claim 27, wherein the first and/or second and/or third and/or fourth varnish layer each comprise different colorants.

29. The method according to claim 1, wherein the first and/or second and/or third and/or fourth varnish layer is applied and/or structured in the form of a graphic motif, alphanumeric character, logo, image, or guilloche pattern.

30. The method according to claim 1, wherein the first varnish layer is applied to a base body which comprises one or more of the following layers: a carrier ply, a detachment layer, a wax layer, a base coat layer, a replication layer with a surface relief, a reflective layer, a protective layer, a volume hologram layer.

31. The method according to claim 30, wherein the surface relief introduced into the replication layer forms an optically variable element, a linear or crossed sinusoidal diffraction grating, a linear or crossed single- or multi-step rectangular grating, a zero-order diffraction structure, an asymmetrical relief structure, a blazed grating, a isotropic or anisotropic mat structure, or a light-diffracting and/or light-refracting and/or light-focusing micro- or nanostructure, a binary or continuous Fresnel lens, a binary or continuous Fresnel free-form surface, a microprism structure or a combined structure thereof.

32. A security element, obtained by means of a method according to claim 1.

33. A banknote, security, identity document, visa document, passport or credit card with a security element multilayer body.
